(19) United States
(12) Patent Application Publication
(10) Pub. No.: US 2026/0026008 A1
(43) Pub. Date: Jan. 22, 2026

(54) INTEGRATED CIRCUIT MEMORY DEVICE HAVING HIGH DEGREES OF VERTICAL INTEGRATION AND METHODS OF FABRICATING SAME

(71) Applicant: Samsung Electronics Co., Ltd., Suwon-si (KR)

(72) Inventor: JEON IL LEE, Suwon-si (KR)

(21) Appl. No.: 19/203,339

(22) Filed: May 9, 2025

(30) Foreign Application Priority Data
Jul. 17, 2024 (KR) 10-2024-0094579

(51) Int. Cl. H10B 51/20; H10B 51/30; H10B 51/40

(52) U.S. Cl. CPC H10B 51/20; H10B 51/30; H10B 51/40

(57) ABSTRACT

An integrated circuit memory device includes a substrate having a cell region therein, a plurality of bit lines extending in a direction perpendicular to the substrate, a plurality of channel patterns having one end connected to each bit line and extending in a first direction intersecting an extension direction of the bit line, and a gate insulating layer, an internal metal layer, a ferroelectric layer, and an external metal layer surrounding each of the channel patterns. The external metal layers surrounding the corresponding channel patterns are connected to each other in a second direction intersecting the first direction.

### REFERENCE TO PRIORITY APPLICATION

This application claims priority to Korean Patent Application No. 10-2024-0094579, filed July 17, 2024, the disclosure of which is hereby incorporated herein by reference.

### BACKGROUND

The present disclosure relates to electronic devices and, more particular, to integrated circuit memory devices.

There is a demand for technology to increase the integration density of integrated circuit memory devices. In the case of conventional two-dimensional integrated circuit memory devices, integration density may be mainly determined by the area occupied by a unit memory cell (i.e., its layout footprint); thus, the maximum degree of integration density that can be achieved may be influenced by the technology used to form fine patterns.

Unfortunately, the very high cost of the equipment and techniques for forming increasingly finer patterns while maintaining sufficiently high yield has become prohibitive. Accordingly, three-dimensional semiconductor memory devices having three-dimensionally arranged memory cells have been proposed.

### SUMMARY

Embodiments are intended to provide integrated circuit memory devices capable of improving operational characteristics, while maintaining sufficiently high fabrication yield.

An integrated circuit memory device according to an embodiment includes a substrate having a cell region therein, a plurality of bit lines extending in a direction perpendicular to the substrate, a plurality of channel patterns having one end connected to each bit line and extending in a first direction intersecting an extension direction of the bit line, and a gate insulating layer, an internal metal layer, a ferroelectric layer, and an external metal layer surrounding each of the channel patterns. According to some embodiments, the external metal layers surrounding the corresponding channel patterns are connected to each other in a second direction intersecting the first direction.

An integrated circuit memory device according to another embodiment includes a substrate, a plurality of bit lines extending in a direction perpendicular to the substrate, a plurality of channel patterns having one end connected to each bit line and extending in a first direction intersecting an extension direction of the bit line, and a gate insulating layer, a ferroelectric layer, and an external metal layer surrounding each of the channel patterns. According to some embodiments, the external metal layers surrounding corresponding channel patterns are connected to each other in a second direction intersecting the first direction.

An integrated circuit memory device according to another embodiment includes a substrate, a plurality of bit lines extending in a direction perpendicular to the substrate, a plurality of channel patterns having one end connected to each bit line and extending in a first direction intersecting an extension direction of the bit line, a gate insulating layer, an internal metal layer, a fixed charge later, an internal metal layer, an antiferroelectric layer, and an external metal layer surrounding each of the channel patterns, and an insulating layer extending between the channel patterns. According to some embodiments, the external metal layers surrounding each channel pattern are connected to each other in a second direction intersecting the first direction.

### BRIEF DESCRIPTION OF THE DRAWINGS

FIG. 1 is a perspective view schematically showing an integrated circuit memory device according to an embodiment.

FIG. 2 is a cross-sectional view taken along line A-A′ of an integrated circuit memory device according to the embodiment of FIG. 1.

FIG. 3 is a cross-sectional view taken along line B-B′ of the integrated circuit memory device of FIG. 2.

FIG. 4 is a cross-sectional view taken along line C-C′ of the integrated circuit memory device of FIG. 2.

FIG. 5 is a cross-sectional view taken along line D-D′ of the integrated circuit memory device of FIG. 2.

FIG. 6 is a cross-sectional view taken along line E-E′ of the integrated circuit memory device of FIG. 2.

FIG. 7 is a cross-sectional view taken along line F-F′ of the integrated circuit memory device of FIG. 2.

FIGS. 8 to 37 are cross-sectional views showing a manufacturing process of the integrated circuit memory device according to the present embodiment.

FIG. 38 shows the same cross-section as FIG. 37 of an integrated circuit memory device according to another embodiment.

FIG. 39 shows the same cross-section as FIG. 37 of an integrated circuit memory device according to another embodiment.

FIG. 40 shows the same cross-section as FIG. 37 of an integrated circuit memory device according to another embodiment.

FIG. 41 schematically shows a plan view of an integrated circuit memory device according to an embodiment.

FIG. 42 shows a plan view of an integrated circuit memory device according to another embodiment.

FIG. 43 shows the same cross-section as FIG. 2 of an integrated circuit memory device according to another embodiment.

FIG. 44 shows the same cross-section as FIG. 2 of an integrated circuit memory device according to another embodiment.

FIG. 45 shows the same cross-section as FIG. 3 of an integrated circuit memory device according to another embodiment.

FIG. 46 shows the same cross-section as FIG. 3 of an integrated circuit memory device according to another embodiment.

FIG. 47 shows the same cross-section as FIG. 2 for another embodiment.

FIG. 48 shows the same cross-section as FIG. 2 for another embodiment.

### DETAILED DESCRIPTION

Hereinafter, the present disclosure will be described in detail with reference to the accompanying drawings, in which embodiments of the present disclosure are shown. As those skilled in the art would realize, the described embodiments may be modified in various different ways, all without departing from the spirit or scope of the present disclosure.

To concisely describe the disclosure, parts that are irrelevant to the description may be omitted, and like reference numerals and/or reference characters refer to like or similar constituent elements throughout the specification. Furthermore, since sizes and thicknesses of constituent members shown in the accompanying drawings may be arbitrarily given to facilitate understanding and ease of description, the disclosure is not limited to the shown sizes and thicknesses; thus, to facilitate understanding and ease of description, the thicknesses of some layers and areas may be exaggerated.

It should be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, in the specification, the word “on” or “above” means positioned on or below the object portion, and does not necessarily mean that it is positioned on the upper side of the object portion based on a gravitational direction.

In addition, unless explicitly stated to the contrary, the word “comprise,” and variations such as “comprises” or “comprising,” should be understood to imply the inclusion of stated elements but not the exclusion of any other elements. Furthermore, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Moreover, as explained more fully hereinbelow, the following reference numbers and designations correspond to regions, patterns and layers as follows: BL: Bit line; SL: Source line; 220: Channel layer; 200: Channel pattern; 410: Internal metal layer; 420: External metal layer; 130: Gate insulating layer; 170: Insulating layer; 131: Ferroelectric layer; 132: Antiferroelectric layer; 134: Fixed charge layer; 180: Dummy pattern; 210: Sacrificial layer; PR: Circuit region; CR: Cell region; and DA: Dummy region.

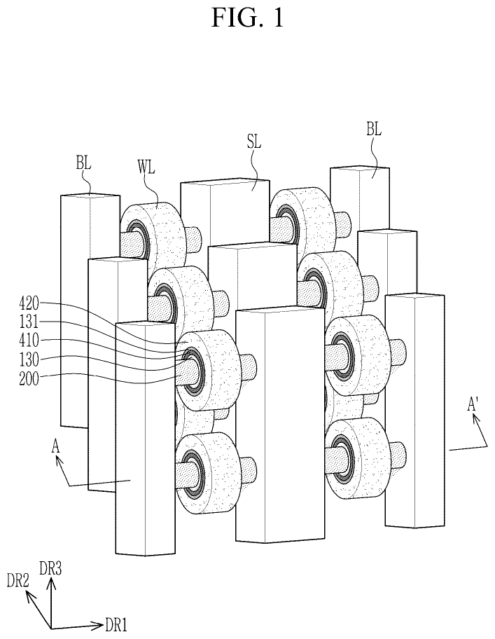

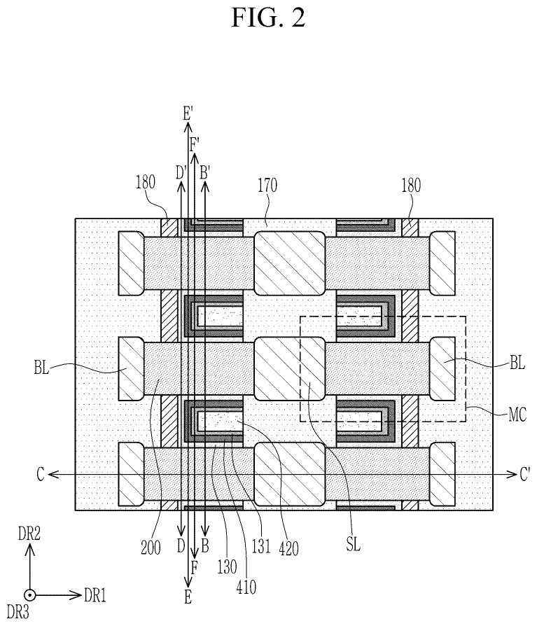

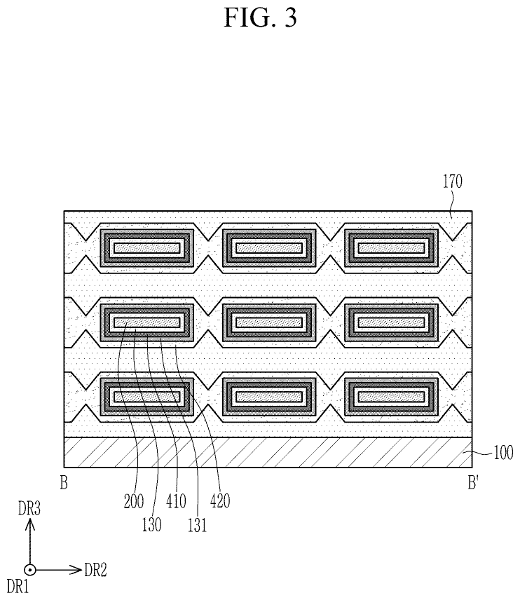

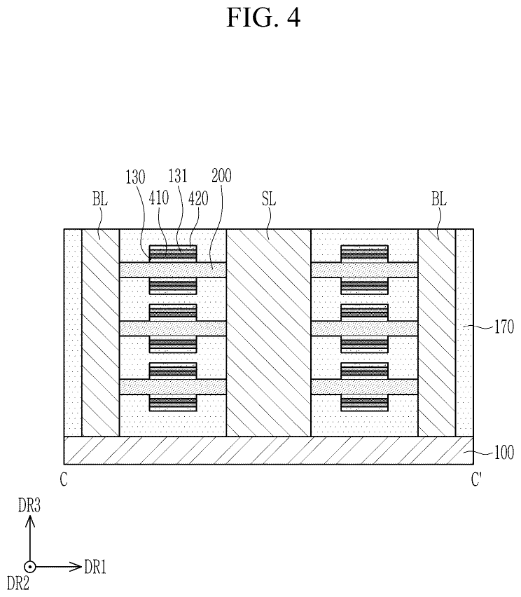

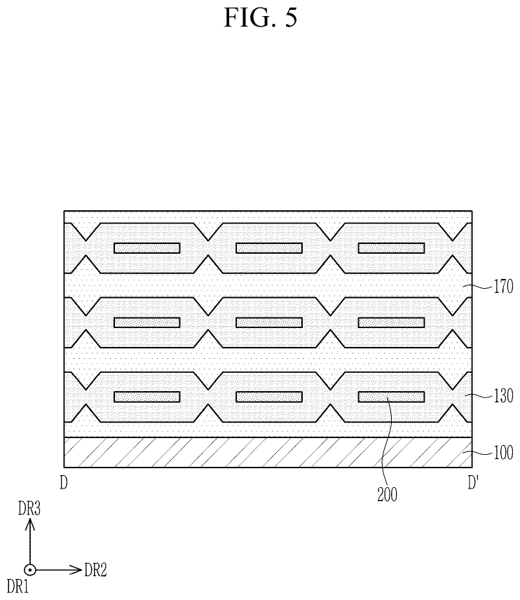

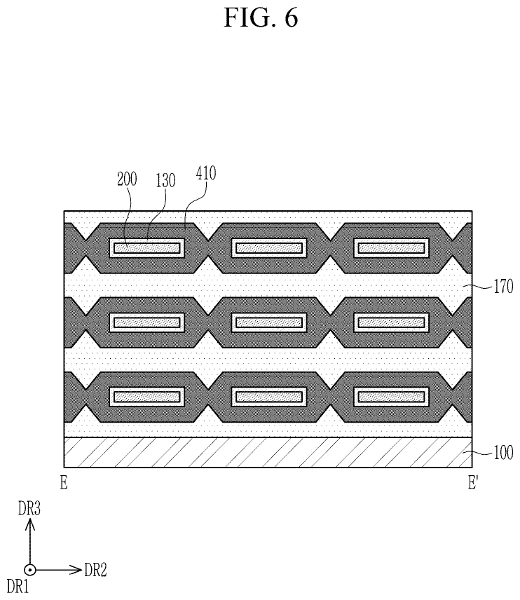

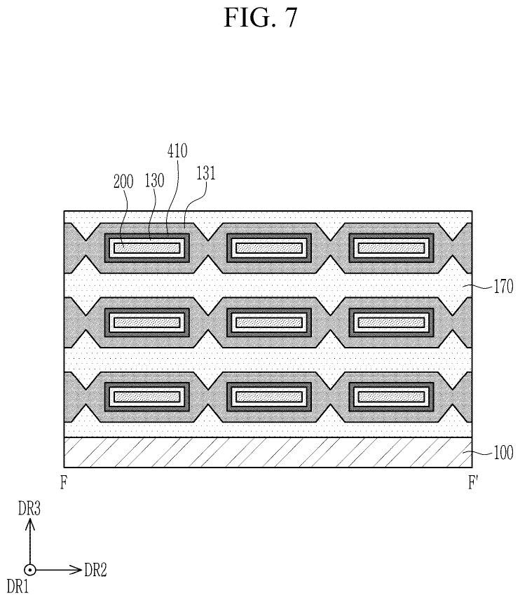

FIG. 1 is a perspective view schematically showing an integrated circuit memory device according to an embodiment. FIG. 2 is a cross-sectional view taken along line A-A′ of an integrated circuit memory device according to the embodiment of FIG. 1. FIG. 3 is a cross-sectional view taken along line B-B′ of the integrated circuit memory device of FIG. 2. FIG. 4 is a cross-sectional view taken along line C-C′ of the integrated circuit memory device of FIG. 2. FIG. 5 is a cross-sectional view taken along line D-D′ of the integrated circuit memory device of FIG. 2. FIG. 6 is a cross-sectional view taken along line E-E′ of the integrated circuit memory device of FIG. 2. FIG. 7 is a cross-sectional view taken along line F-F′ of the integrated circuit memory device of FIG. 2.

Referring to FIG. 1, an integrated circuit memory device according to the present embodiment may include a bit line BL and a source line SL extending along a third direction DR3, a channel pattern 200 disposed between the bit line BL and the source line SL and disposed in a first direction DR1, and a word line WL disposed surrounding the channel pattern 200 and extending in a second direction DR2. As shown in FIG. 1, the channel pattern 200 disposed between the bit line BL and the source line SL may be surrounded by a gate insulating layer 130, an internal metal layer 410, a ferroelectric layer 131, and an external metal layer 420. At this time, the external metal layer 420 surrounding each channel pattern 200 may be in contact with the external metal layer 420 surrounding the adjacent channel pattern 200. Accordingly, the external metal layer 420 surrounding each channel pattern 200 may be joined together in the second direction DR2. The external metal layer 420 may function as a word line WL.

In FIG. 1, for convenience of illustration, only a portion of the gate insulating layer 130, internal metal layer 410, ferroelectric layer 131, and external metal layer 420 surrounding the channel pattern 200 are shown. In particular, in order to show a cross-section of the structure surrounding the channel pattern 200, only a portion of the region surrounding the channel pattern 200 is shown, and the gate insulating layer 130, internal metal layer 410, ferroelectric layer 131, and external metal layer 420 surrounding the channel pattern 200 may have the shape shown in FIG. 2.

As shown in FIG. 2, the gate insulation layer 130, inner metal layer 410, ferroelectric layer 131, and outer metal layer 420 may have different shapes formed at both edges in the first direction DR1 of the channel pattern 200. Additionally, for convenience of illustration, the description of a dummy pattern 180 is omitted in FIG. 1, but as shown in FIG. 2, the channel pattern 200 may be surrounded by the dummy pattern 180.

In FIG. 1, the channel pattern 200 is shown in a cylindrical shape, but this is an example and the shape of the channel pattern 200 is not limited thereto; for example, the channel pattern 200 may have a square pillar shape. In this case, the corners of the square pillars of the channel pattern 200 may include curved surfaces. That is, the shape of the channel pattern 200 may not be limited to a specific shape. In addition, in FIG. 1, the width of the bit line BL and the source line SL in the second direction DR2 is shown to be greater than the width of the channel pattern 200 in the second direction DR2, but this is only an example, and the width of the bit line BL and the source line SL in the second direction DR2 may be equal to the width of the channel pattern 200 in the second direction DR2.

The bit line BL and the source line SL may each include a conductive material. For example, each of the bit line BL and the source line SL may include at least one material selected from a group consisting of a doped semiconductor material (e.g., doped silicon, doped germanium), a conductive metal nitride (e.g., titanium nitride, tantalum nitride), metals (e.g., tungsten, titanium, tantalum), or metal-semiconductor compounds (e.g., tungsten silicide, cobalt silicide, titanium silicide), but is not limited thereto.

In FIG. 1, a configuration is shown in which a plurality of source lines SL extend along a third direction DR3 and are spaced apart in the second direction DR2, but is not limited thereto. In another embodiment, the source line SL may be disposed such that the source line SL extends along the third direction DR3 and continues in the second direction DR2. Additionally, in FIG. 1, a configuration in which two channel patterns 200 adjacent to each other in the first direction DR1 share one source line SL is shown, but the configuration is not limited thereto. In another embodiment, each channel pattern 200 may be connected to each source line SL.

The channel pattern 200 may be disposed in the first direction DR1 between the bit line BL and the source line SL. The channel pattern 200 may include at least one of a semiconductor material, an amorphous oxide semiconductor material, or a two-dimensional material. In an embodiment, the channel pattern 200 may include at least one selected from polysilicon, doped silicon (Si), silicon germanium (SiGe), or a semiconductor formed by selective epitaxial growth (SEG). The channel pattern 200 may have a single-layer or multi-layer structure.

In an embodiment, the channel pattern 200 may include an amorphous oxide semiconductor material—for example, a compound of at least two metals selected from zinc (Zn), indium (In), gallium (Ga), or tin (Sn) and oxygen (O). For example, the channel pattern 200 may include at least one selected from indium gallium zinc oxide (IGZO), indium tin zinc oxide (ITZO), Sn-IGZO, IWO, CuS₂, CuSe₂, WSe₂, IZO, ZTO, or YZO, but is not limited thereto. In an embodiment, the channel pattern 200 may include a two-dimensional material. For example, the channel pattern 200 may include metal chalcogenide, transition metal chalcogenide, graphene, or phosphorene. In addition, when a gate-on signal is applied to the word line WL and a predetermined voltage is applied to the bit line BL and the source line SL, current may flow from the source line SL to the bit line BL through the channel pattern 200.

Referring to FIGS. 1 to 7 simultaneously, the channel pattern 200 may be surrounded by the gate insulating layer 130. The gate insulating layer 130 may include, for example, a silicon oxide layer, a silicon oxynitride layer, a high dielectric layer having a higher dielectric constant than the silicon oxide layer, or a combination thereof. The high dielectric layer may include, for example, metal oxide or metal oxynitride.

As shown in FIG. 3, the gate insulating layer 130 may be disposed surrounding the channel pattern 200. In the cross-section of FIG. 3, the gate insulating layer 130 is shown to be separate for each of the channel patterns 200, but with simultaneous reference to FIGS. 2 and 5, the gate insulating layer 130 surrounding each of the channel patterns 200 may be joined together along the second direction DR2 between the plurality of channel patterns 200.

The internal metal layer 410 may be disposed surrounding the gate insulating layer 130. The internal metal layer 410 may include at least one of metal materials such as titanium, tantalum, tungsten, copper, or aluminum, a conductive metal nitride such as titanium nitride or tantalum nitride, or a doped semiconductor material such as doped silicon or doped germanium.

As shown in FIG. 3, the internal metal layer 410 may be disposed surrounding the channel pattern 200 and the gate insulating layer 130. In the cross-section of FIG. 3, the internal metal layer 410 is shown to be separate for each of the channel patterns 200, but with simultaneous reference to FIGS. 2 and 6, the internal metal layer 410 surrounding each of the channel patterns 200 may be joined together along the second direction DR2 between the plurality of channel patterns 200.

Due to the internal metal layer 410, a memory window of the integrated circuit memory device may be improved and the durability of the gate insulating film may be improved. A separate voltage may not be applied to the internal metal layer 410. However, this is an example, and a voltage may be applied to the internal metal layer 410.

The ferroelectric layer 131 may be disposed surrounding the internal metal layer 410. The ferroelectric layer 131 may include a ferroelectric material. In an embodiment, the ferroelectric material may include an Hf compound. The Hf compound may be, for example, an Hf-based oxide. The Hf-based oxide may further include at least one impurity selected from Zr, Si, Al, Y, Gd, La, Sc, or Sr. The ferroelectric material may include, for example, HfO₂, HfZnO, HfSiO, HfSiON, HfTaO, HfTiO, HfZrO, or a combination thereof. The ferroelectric layer 131 may have an orthorhombic phase. The ferroelectric layer 131 may include a single layer, a multilayer in which two or more types of ferroelectric layers are stacked, or a multilayer in which a ferroelectric layer and a dielectric layer are stacked.

According to an embodiment, the ferroelectric layer 131 may have various polarization states depending on the voltage applied between the bit line BL and the source line SL and the word line WL. According to an embodiment, the current value flowing from the source line SL to the bit line BL through the channel pattern 200 may be determined based on the polarization state of the ferroelectric layer 131.

As shown in FIG. 3, the ferroelectric layer 131 may be disposed surrounding the channel pattern 200. In the cross-section of FIG. 3, the ferroelectric layer 131 is shown to be separate for each of the channel patterns 200, but with simultaneous reference to FIGS. 2 and 7, the ferroelectric layer 131 surrounding each of the channel patterns 200 may be joined as one between the plurality of channel patterns 200.

The external metal layer 420 may be disposed surrounding the ferroelectric layer 131. The external metal layer 420 may include at least one of metal materials such as titanium, tantalum, tungsten, copper, or aluminum, a conductive metal nitride such as titanium nitride or tantalum nitride, or a doped semiconductor material such as doped silicon or doped germanium.

As shown in FIG. 3, the external metal layers 420 surrounding each channel pattern 200 may be joined as one in the second direction DR2. Referring to FIG. 1, the external metal layer 420 surrounding each channel pattern 200 may extend in the second direction DR2. The external metal layer 420 may form the word line WL of an integrated circuit memory device.

Referring to FIGS. 2 and 3, the external metal layer 420 may be disposed while filling the space between adjacent channel patterns 200 in the second direction DR2. Accordingly, the external metal layers 420 of adjacent channel patterns 200 in the second direction DR2 may be joined as one. Referring to FIGS. 3 and 4, the external metal layer 420 may be spaced apart from adjacent channel patterns 200 in the third direction DR3. Accordingly, the external metal layers 420 of the adjacent channel patterns 200 in the third direction DR3 may be separated from each other.

Referring to FIGS. 1 to 7, an insulating layer 170 may be disposed in the space between the bit line BL, the source line SL, and the channel pattern 200. The insulating layer 170 may include at least one of silicon oxide, silicon nitride, silicon oxynitride, carbon-containing silicon oxide, carbon-containing silicon nitride, or carbon-containing silicon oxynitride. For example, the insulating layer 170 may include silicon oxide.

Referring to FIG. 3, the insulating layer 170 may separate the channel patterns 200 disposed side by side in the third direction DR3. The insulating layer 170 may be disposed side by side along the second direction DR2, and the thickness of the insulating layer extending along the second direction DR2 and disposed in the third direction DR3 may be different in regions where the channel pattern 200 is disposed and in regions where the channel pattern 200 is not disposed, as shown in FIG. 3.

Additionally, referring again to FIG. 2, the dummy pattern 180 surrounding the channel pattern 200 may be disposed. The dummy pattern 180 may surround the channel pattern 200 while being in direct contact with the channel pattern 200. As shown in FIG. 2, the dummy pattern 180 may be disposed in contact with the gate insulating layer 130. As will be described separately later, the dummy pattern 180 may be configured to form the insulating layer 170 that separates the channel pattern 200 in the third direction DR3 as shown in FIG. 3. The dummy pattern 180 may include at least one of silicon oxide, silicon nitride, silicon oxynitride, carbon-containing silicon oxide, carbon-containing silicon nitride, or carbon-containing silicon oxynitride. However, the dummy pattern 180 may include a material different from the insulating layer 170. Specifically, the dummy pattern 180 may include a material having an etch selectivity with respect to the material of the insulating layer 170. For example, the dummy pattern 180 may include silicon nitride. In an embodiment, the insulating layer 170 may include silicon oxide and the dummy pattern 180 may include silicon nitride.

As shown in FIG. 2, the gate insulating layer 130, internal metal layer 410, ferroelectric layer 131, and external metal layer 420 surrounding the channel pattern 200 may configure one memory cell MC. That is, the integrated circuit memory device according to the present embodiment includes a plurality of memory cells MC, and each of the plurality of memory cells MC may include the source line SL, the bit line BL, the channel pattern 200 disposed between the source line SL and the bit line BL, the gate insulating layer 130, the internal metal layer 410, the ferroelectric layer 131, and the external metal layer 420 as a word line.

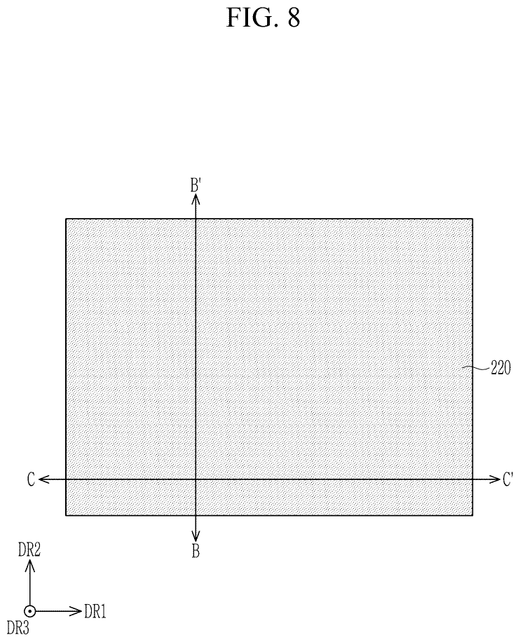

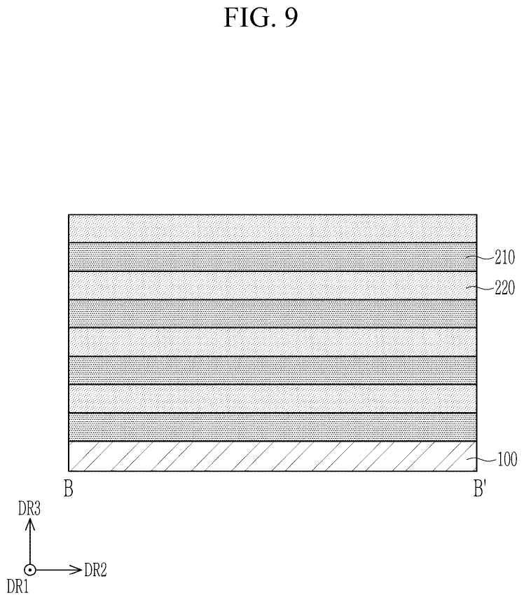

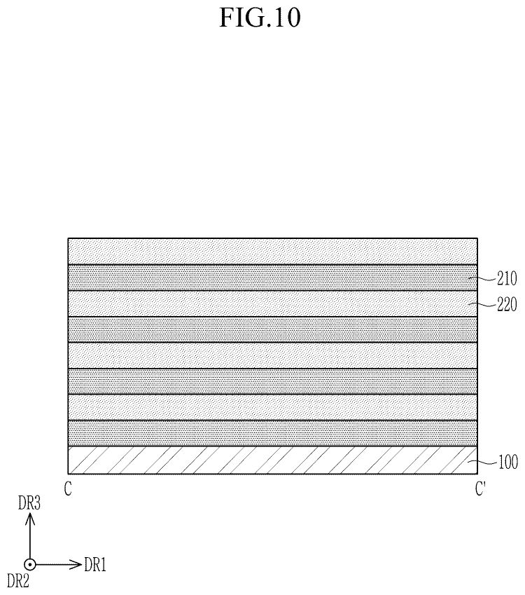

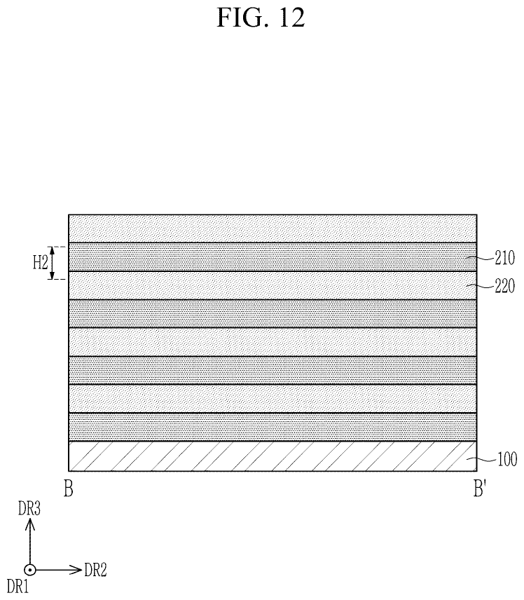

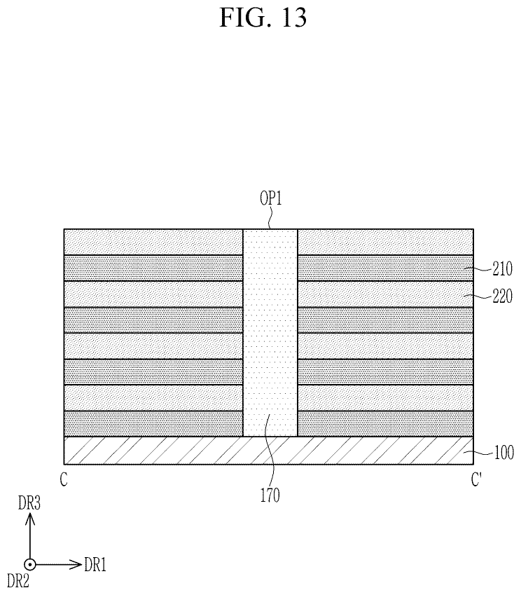

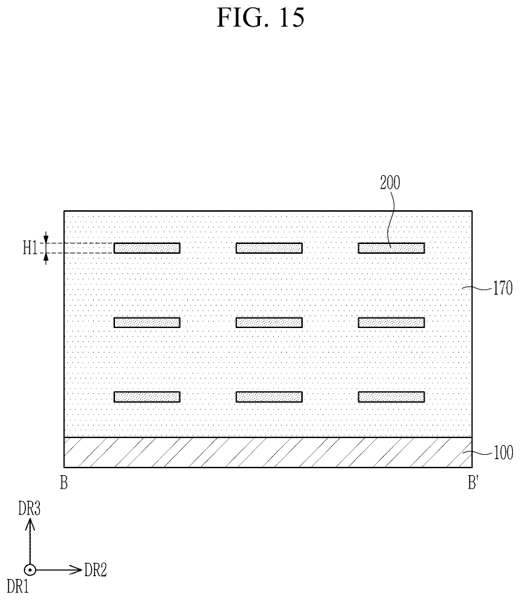

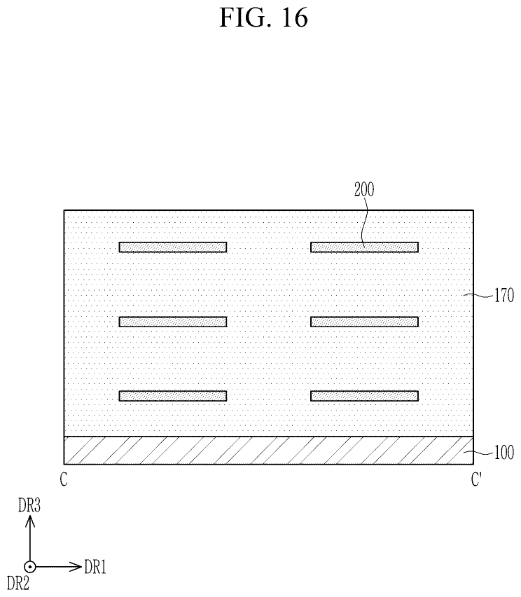

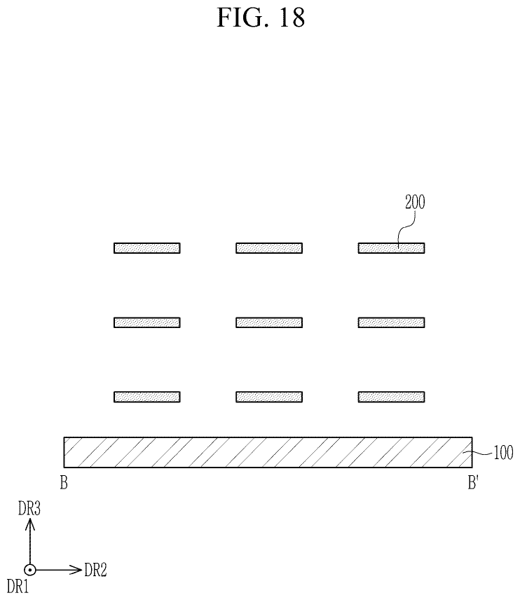

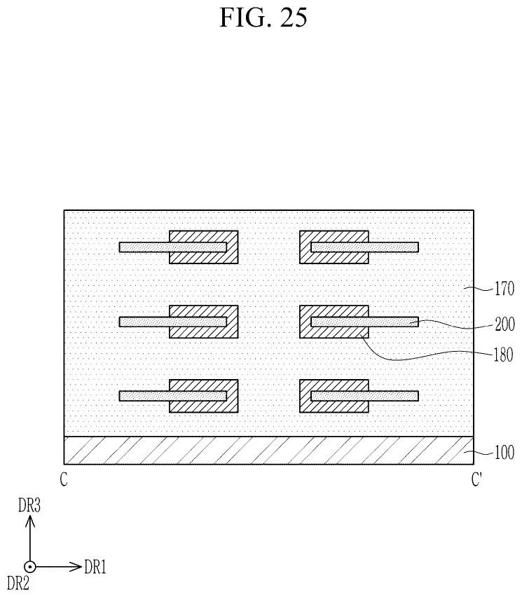

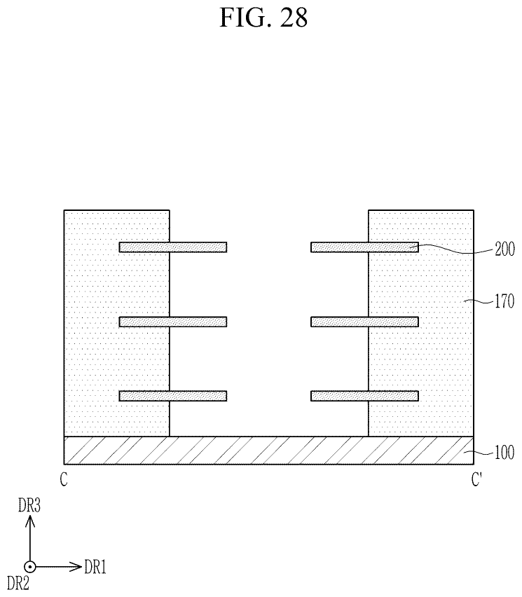

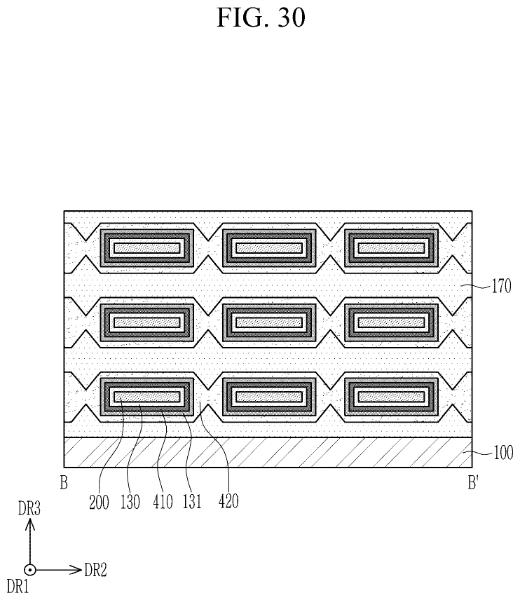

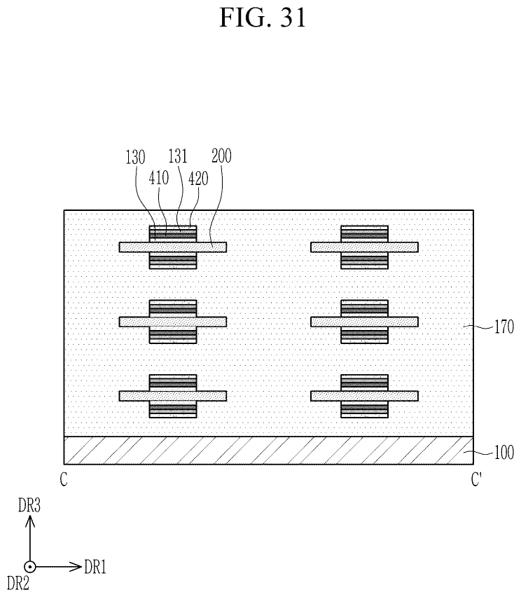

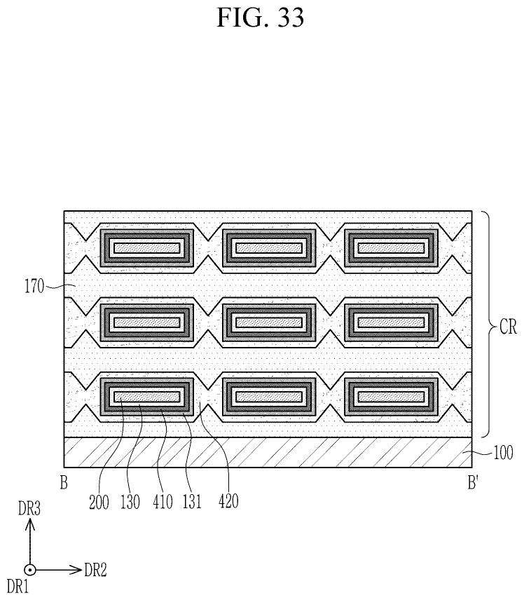

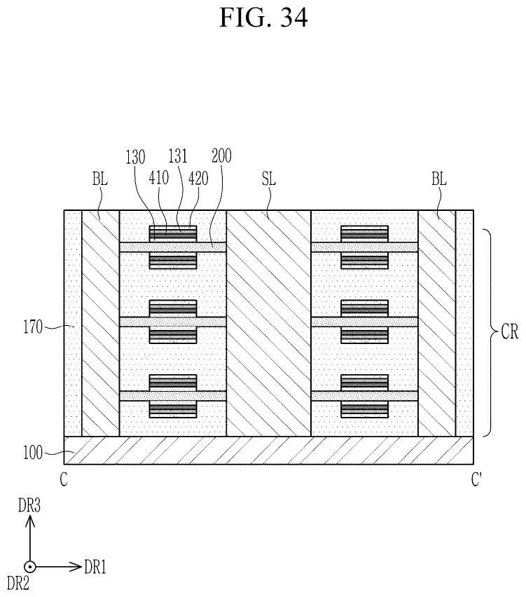

Hereinafter, a manufacturing method of the integrated circuit memory device according to the present embodiment will be described below with reference to the drawings. FIGS. 8 to 37 are cross-sectional views showing a manufacturing process of the integrated circuit memory device according to the present embodiment. FIGS. 8, 11, 14, 17, 20, 23, 26, 29, 32, and 35 show the same cross-section as FIG. 2 during the manufacturing process, and FIGS. 9, 12, 15, 18, 21, 24, 27, 30, 33 and 36 show the same cross-section as in FIG. 3 during the manufacturing process. FIGS. 10, 13, 16, 19, 22, 25, 28, 31, 34, and 37 show the same cross-section as FIG. 4 during the manufacturing process. That is, the cross-sections shown in FIGS. 8, 11, 14, 17, 20, 23, 26, 29, 32, and 35 cut along lines B-B′ correspond to FIGS. 9, 12, 15, 18, 21, 24, 27, 30, 33, and 36, and the cross-sections shown in FIGS. 8, 11, 14, 17, 20, 23, 26, 29, 32, and 35 cut along lines C-C′ correspond to FIGS. 10, 13, 16, 19, 22, 25, 28, 31, 34, and 37.

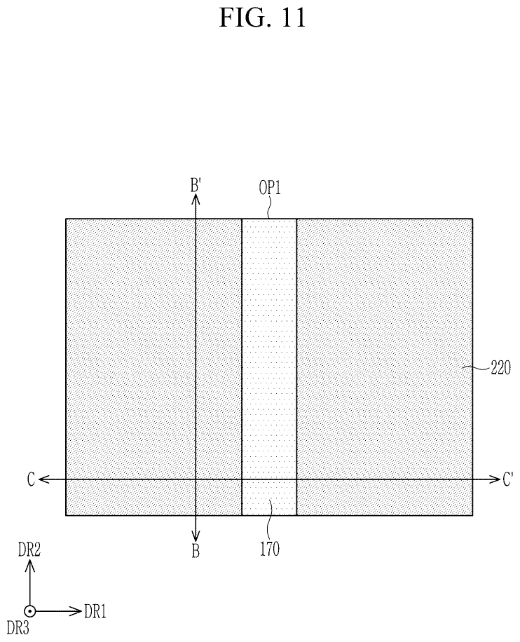

Referring to FIGS. 8 to 10, channel layers 220 and sacrificial layers 210 are alternately stacked on the substrate 100. Next, referring to FIGS. 11 to 13, a first open portion OP1 is formed in a laminate, and the first open portion OP1 is filled with a material of the insulating layer 170. The material of the insulating layer 170 is the same as previously described. The material of the insulating layer 170 may include at least one of silicon oxide, silicon nitride, silicon oxynitride, carbon-containing silicon oxide, carbon-containing silicon nitride, or carbon-containing silicon oxynitride. For example, the material of the insulating layer 170 may include silicon oxide.

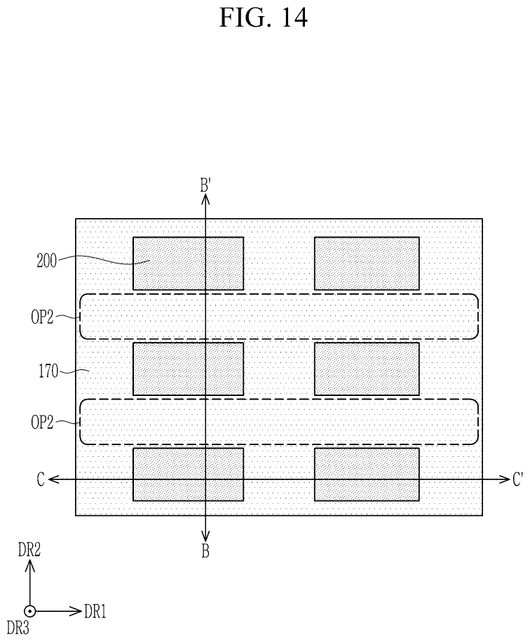

Next, referring to FIGS. 14 to 16, a second open portion OP2 is formed in a direction intersecting the first open portion OP1 and a stacking structure is etched. The sacrificial layer 210 of the stacking structure is removed through the second open portion OP2. In this process, the channel layer 220 may be additionally etched to reduce the thickness of the channel layer 220. When the thickness of the channel layer 220 is reduced in this way, there is an advantage in that the floating body effect is minimized and defects in the channel layer are easily controlled. However, the additional etching process for the channel layer 220 is optional, and the etching process for the channel layer 220 may be omitted. In this case, the thickness of the previously stacked channel layer 220 and the thickness of the channel pattern 200 of the final manufactured integrated circuit memory device may be the same.

Next, the material of the insulating layer 170 is filled in the area where the sacrificial layer 210 has been removed. Through this process, a plurality of channel patterns 200 may be formed inside the insulating layer 170 as shown in FIGS. 14 to 16. As described above, the thickness H1 of the channel pattern 200 may be less than the thickness H2 of the channel layer 220 stacked in the previous step when the etching process of the channel layer 220 is performed. However, when the etching process of the channel layer 220 is not performed, the thickness H1 of the channel pattern 200 may be the same as the thickness H2 of the channel layer 220 in the previous step.

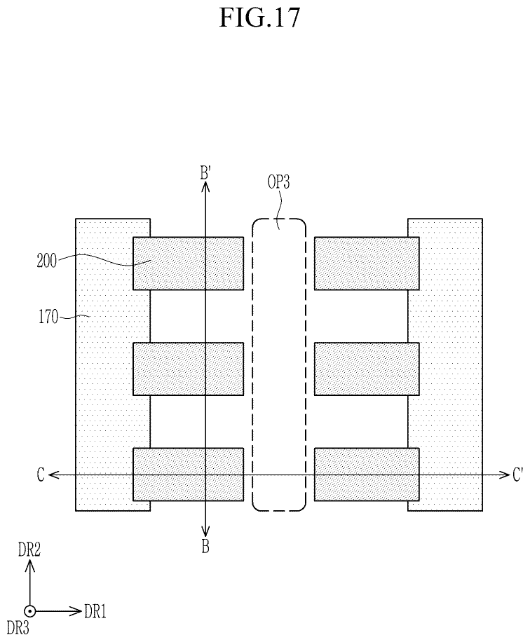

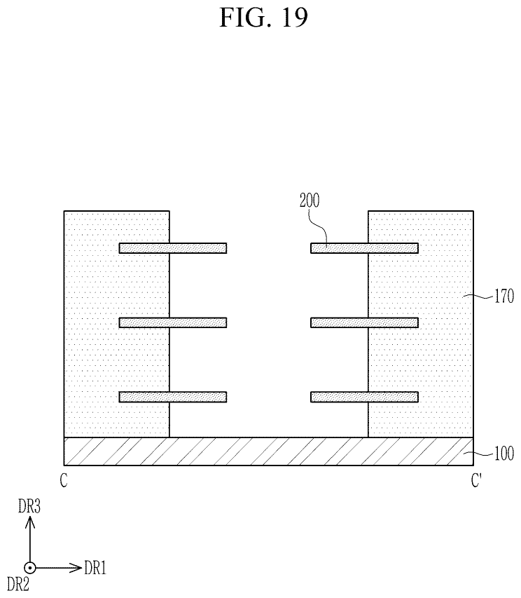

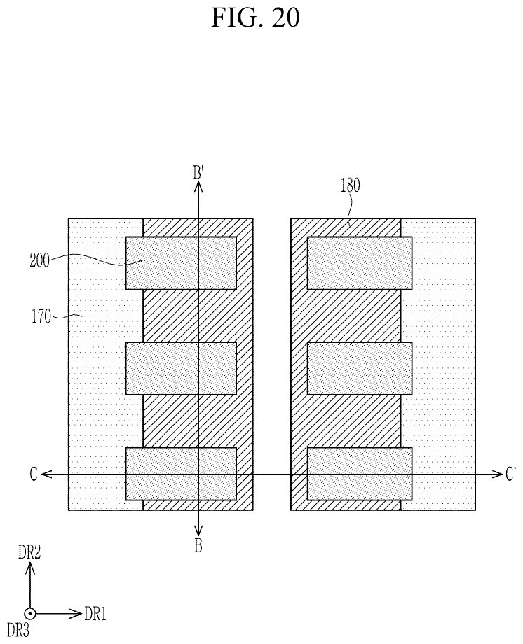

Next, referring to FIGS. 17 to 19, a third open portion OP3 is formed and a portion of the insulating layer 170 is removed through the third open portion OP3. As shown in FIG. 19, the channel pattern 200 may be supported by the remaining insulating layer 170 without being removed. Next, referring to FIGS. 20 to 22, the dummy pattern 180 may be formed surrounding the channel pattern 200. As shown in FIGS. 20 to 22, the dummy pattern 180 may be formed to surround the channel pattern 200. The material of the dummy pattern 180 is the same as previously described. The dummy pattern 180 may include at least one of silicon oxide, silicon nitride, silicon oxynitride, carbon-containing silicon oxide, carbon-containing silicon nitride, or carbon-containing silicon oxynitride. However, the dummy pattern 180 may include a material different from the insulating layer 170. Specifically, the dummy pattern 180 may include a material having an etch selectivity with respect to the material of the insulating layer 170. For example, the dummy pattern 180 may include silicon nitride. In an embodiment, the insulating layer 170 may include silicon oxide and the dummy pattern 180 may include silicon nitride.

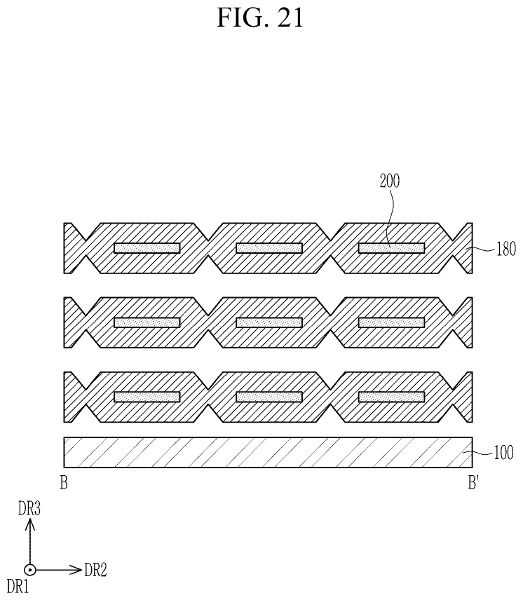

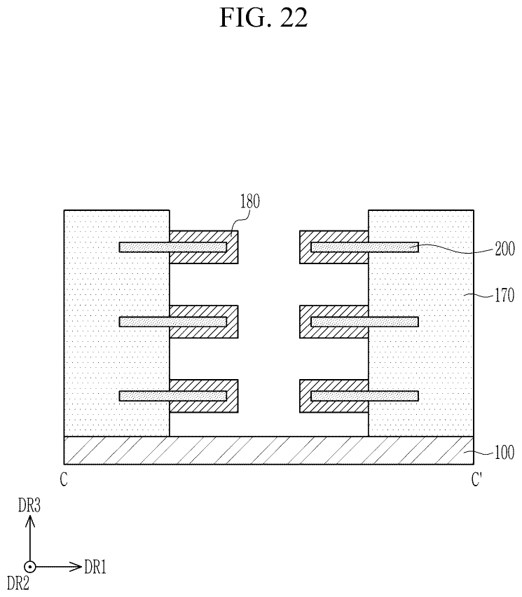

As shown in FIG. 21, the dummy pattern 180 is disposed surrounding each channel pattern 200 and may be connected in the second direction DR2 to the dummy pattern 180 surrounding the adjacent channel pattern 200. As shown in FIGS. 21 and 22, the dummy patterns 180 surrounding each channel pattern 200 may be spaced apart from each other in the third direction DR3.

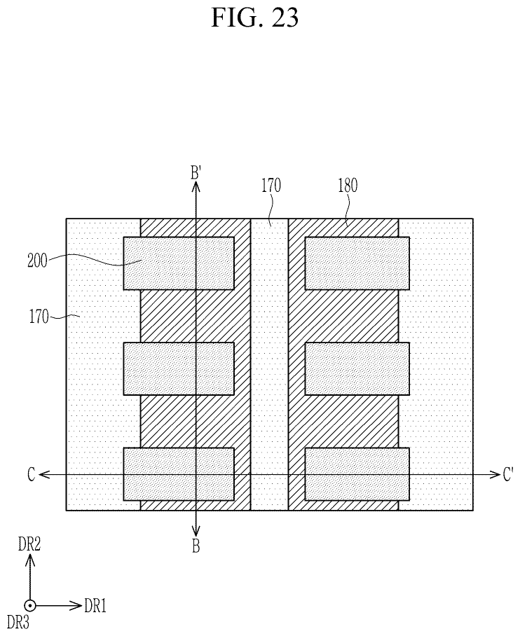

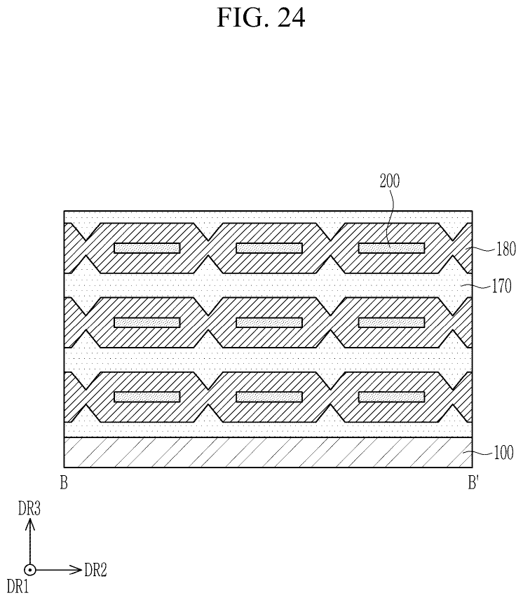

Next, referring to FIGS. 23 to 25, the region where the dummy pattern 180 is not formed is filled with the material of the insulating layer 170. Through this process, as shown in FIG. 24, the space between the dummy patterns 180 spaced apart in the third direction DR3 may be filled with the insulating layer 170. Referring to FIG. 24, the insulating layer 170 extends along the second direction DR2 and may separate the channel patterns 200 adjacent from each other in the third direction DR3.

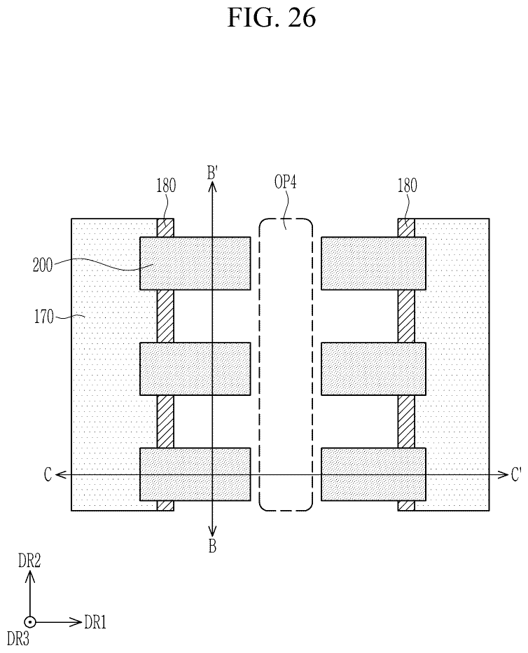

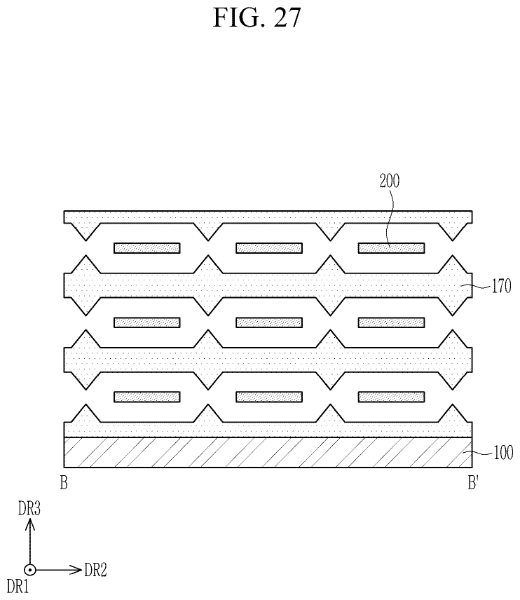

Next, referring to FIGS. 26 to 28, a fourth open portion OP4 is formed and the insulating layer 170 and the dummy pattern 180 are removed. Through this process, as shown in FIG. 27, the channel patterns 200 disposed side by side in the third direction DR3 may be separated by the insulating layer 170. Additionally, the dummy pattern 180 surrounding the channel pattern 200 may be etched. The etching may be performed until some of the dummy pattern 180 surrounding the channel pattern 200 remains, as shown in FIG. 26. However, this is only an example and etching may be performed until the dummy pattern 180 is completely etched. In this case, the dummy pattern 180 may not be included in the final manufactured integrated circuit memory device.

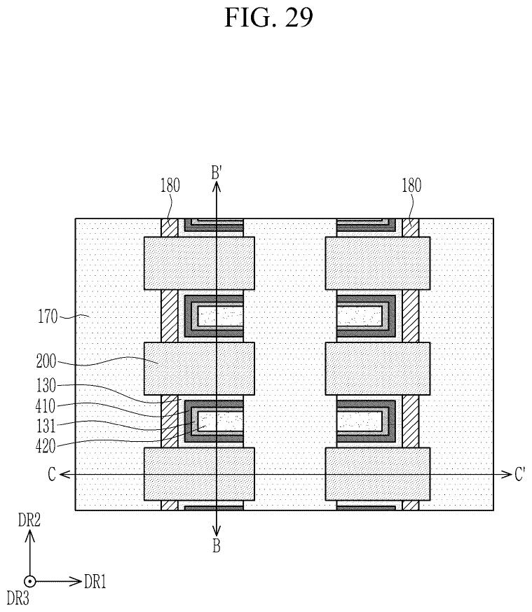

Next, referring to FIGS. 29 to 31, the gate insulating layer 130, the internal metal layer 410, the ferroelectric layer 131, and the external metal layer 420 surrounding the channel pattern 200 are sequentially formed. The gate insulating layer 130, internal metal layer 410, ferroelectric layer 131, and external metal layer 420 may be formed by atomic laser deposition (ALD).

The materials of the gate insulating layer 130, the internal metal layer 410, the ferroelectric layer 131, and the external metal layer 420 are the same as described above. The gate insulating layer 130 may include, for example, a silicon oxide layer, a silicon oxynitride layer, a high dielectric layer having a higher dielectric constant than the silicon oxide layer, or a combination thereof. The high dielectric layer may include, for example, metal oxide or metal oxynitride. The internal metal layer 410 and the external metal layer 420 may include at least one of metal materials such as titanium, tantalum, tungsten, copper, or aluminum, a conductive metal nitride such as titanium nitride or tantalum nitride, or a doped semiconductor material such as doped silicon or doped germanium.

The ferroelectric layer 131 may include a ferroelectric material. In an embodiment, the ferroelectric material may include the Hf compound. The Hf compound may be, for example, an Hf-based oxide. The Hf-based oxide may further include at least one impurity selected from Zr, Si, Al, Y, Gd, La, Sc, or Sr. The ferroelectric material may include, for example, HfO₂, HfZnO, HfSiO, HfSiON, HfTaO, HfTiO, HfZrO, or a combination thereof. The ferroelectric layer 131 may have an orthorhombic phase. The ferroelectric layer 131 may include a single layer, a multilayer in which two or more types of ferroelectric layers are stacked, or a multilayer in which a ferroelectric layer and a dielectric layer are stacked.

The gate insulating layer 130, the internal metal layer 410, the ferroelectric layer 131, and the external metal layer 420 may be formed to sequentially surround the entire channel pattern 200 that is not covered by the insulating layer 170, and are then formed into the shape shown in FIGS. 29 to 31 through the etching process. That is, as shown in FIG. 29, one end of the channel pattern 200 may not be covered by the gate insulating layer 130, the internal metal layer 410, the ferroelectric layer 131, and the external metal layer 420 through the etching process.

After etching of the gate insulating layer 130, the internal metal layer 410, the ferroelectric layer 131, and the external metal layer 420 into the shapes shown in FIGS. 29 to 31, the remaining space may be filled with the insulating layer 170. Therefore, as shown in FIG. 29, one end of the gate insulating layer 130, the internal metal layer 410, the ferroelectric layer 131, and the external metal layer 420 may be in direct contact with the insulating layer 170.

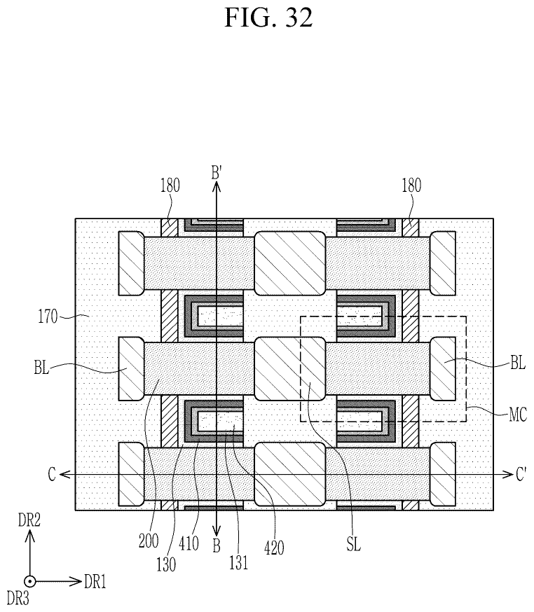

Next, referring to FIGS. 32 to 34, the bit line BL and the source line SL are formed in contact with each channel pattern 200. At this time, the bit line BL and the source line SL may be formed by forming an opening in the insulating layer 170 and filling the opening with a conductive material. According to some embodiments, each of the bit line BL and the source line SL may include at least one selected from a doped semiconductor material (e.g., doped silicon, doped germanium), a conductive metal nitride (e.g., titanium nitride, tantalum nitride), metals (e.g., tungsten, titanium, tantalum), or metal-semiconductor compounds (e.g., tungsten silicide, cobalt silicide, titanium silicide), but is not limited thereto. Through this process, a cell region CR in which a plurality of memory cells MC are stacked may be manufactured.

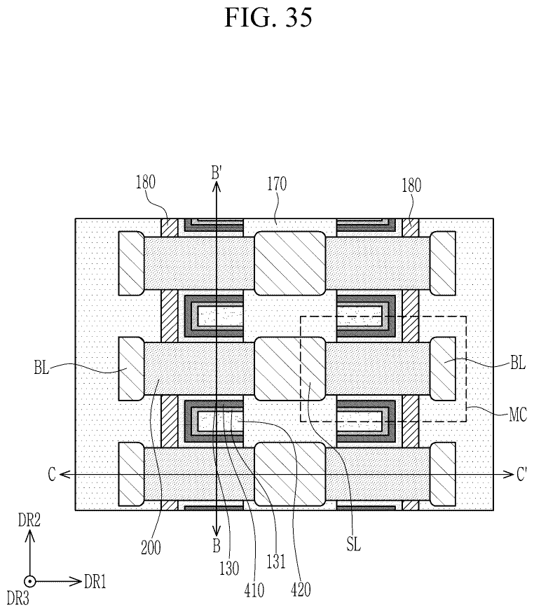

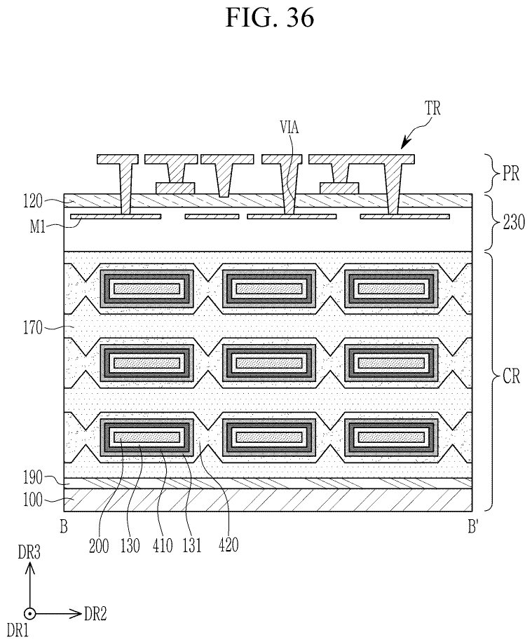

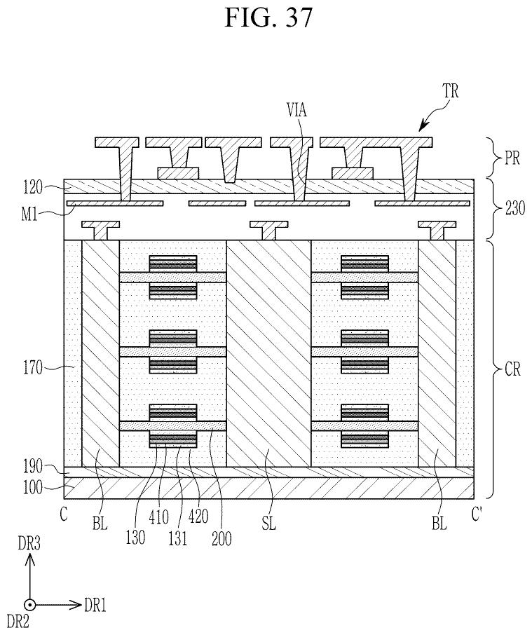

Next, referring to FIGS. 35 to 37, the substrate 100 is removed and a substrate insulating layer 190 and a carrier substrate 110 are formed. The carrier substrate 110, the bit line BL, and the source line SL may be insulated by the substrate insulating layer 190. As shown in FIGS. 36 and 37, a wiring layer 230 and a circuit region PR are formed on one surface where the substrate insulating layer 190 and the carrier substrate 110 are not formed. The wiring layer 230 may include a wiring M1 connected to each bit line BL and source line SL.

The circuit region PR may include a circuit board 120 and a transistor TR disposed on the circuit board 120. The transistor TR may be connected to the wiring M1 of the wiring layer 230 through a via VIA. After forming the wiring layer 230 on the cell region CR, the circuit board 120 including the transistor may be bonded. At this time, the upper surface of the wiring layer 230 and the lower surface of the circuit board 120 (i.e., the bonding surface of the wiring layer 230 and the circuit board 120) may each include a silicon oxide layer and may be attached by direct bonding.

After attaching the circuit board 120 including the transistor TR on the wiring layer 230, the via VIA penetrating the circuit board 120 and the wiring layer 230 may be formed to connect the transistor TR and the wiring M1 of the wiring layer 230. Accordingly, the transistor TR in the circuit region PR and the bit line BL and source line SL in the cell region CR may be connected. However, this is an example, and the present disclosure is not limited thereto.

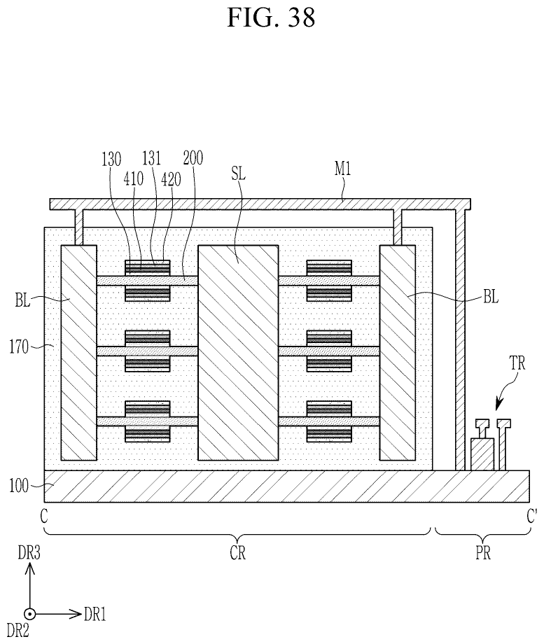

FIGS. 35 to 37 show configurations in which the circuit region PR is disposed on the cell region CR, but this is an example, and the arrangement of the circuit region PR may vary. FIG. 38 shows the same cross-section as FIG. 37 of an integrated circuit memory device according to another embodiment. Referring to FIG. 38, in the integrated circuit memory device according to the present embodiment, the circuit region PR may be disposed side by side with the cell region CR. That is, the circuit region PR and the cell region CR are formed on the same surface of the substrate 100, and the bit line BL and the source line SL of the cell region CR may be connected to the transistor TR of the circuit region PR through the separate wiring M1. In the embodiment of FIG. 38, the bit line BL and the source line SL do not directly contact the substrate 100, so the bit line BL and the source line SL may be insulated from the substrate 100.

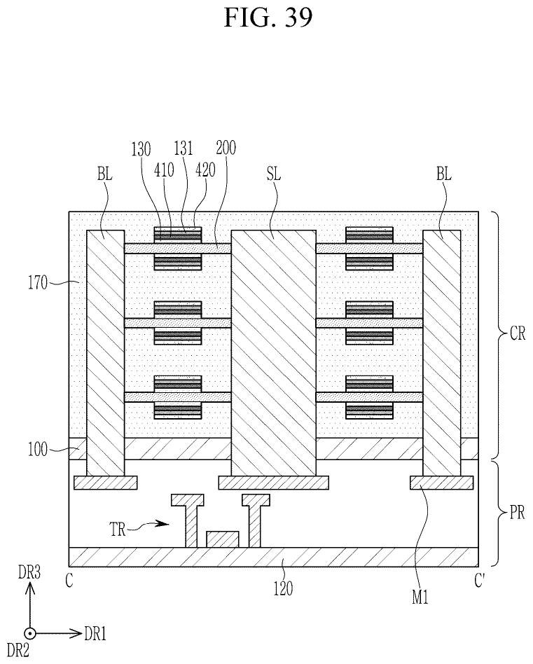

FIG. 39 shows the same cross-section as FIG. 37 of an integrated circuit memory device according to another embodiment. Referring to FIG. 39, in the integrated circuit memory device according to the present embodiment, the circuit region PR may be disposed below the cell region CR. The circuit board 120 and the transistor TR may be disposed in the lower part of the cell region CR, and the bit line BL and the source line SL may penetrate the substrate 100 and be connected to the wiring M1 of the circuit region PR. Although not shown in FIG. 39, an insulating layer may be disposed between the substrate 100 and the bit line BL and the source line SL, so that the substrate 100, the bit line BL, and the source line SL may be insulated.

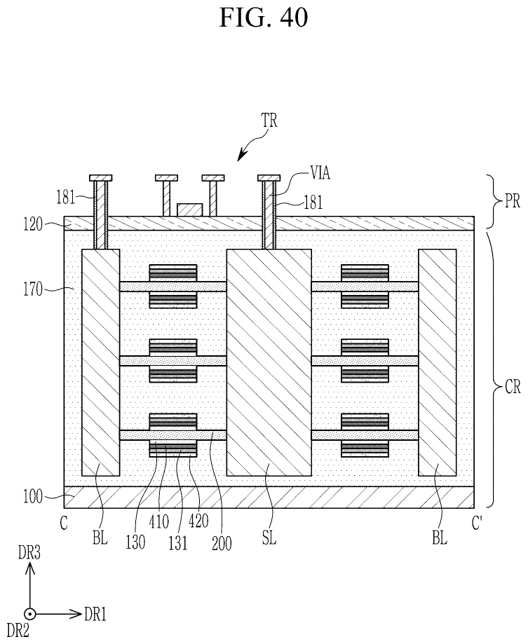

FIG. 40 shows the same cross-section as FIG. 37 of an integrated circuit memory device according to another embodiment. Referring to FIG. 40, the integrated circuit memory device according to the present embodiment may have the circuit region PR disposed on the cell region CR. That is, the circuit board 120 is disposed directly on the cell region CR without a separate wiring layer, and the transistor TR disposed on the circuit board 120 may be directly connected to the bit line BL and the source line SL through the via VIA, which penetrates the circuit board 120. An insulating layer 181 is disposed on the side surface of the via VIA so that the via VIA and the circuit board 120 may not be in direct contact. At this time, the circuit board 120 may include monocrystalline silicon, but is not limited thereto. In the embodiment of FIG. 40, the bit line BL and the source line SL do not contact the substrate 100, so the bit line BL and the source line SL may be insulated from the substrate 100.

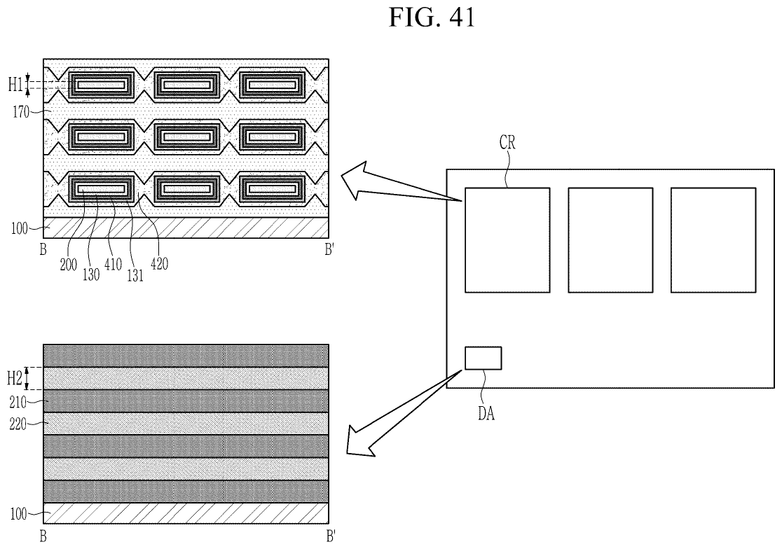

FIG. 41 schematically shows a plan view of an integrated circuit memory device according to an embodiment. Referring to FIG. 41, the integrated circuit memory device may include the cell region CR and a dummy region DA. The stacking structure of the cell region CR is as described above. The dummy region DA may have a stacking structure as shown in FIGS. 9 and 10. That is, the dummy region DA may have a structure in which the channel layers 220 and the sacrificial layers 210 are alternately stacked.

At this time, the thickness H1 of the channel pattern 200 included in the cell region CR may be less than the thickness H2 of the channel layer 220 included in the dummy region DA. This is because the process of forming the channel pattern 200 by patterning the channel layer 220 includes a process of reducing the thickness of the channel pattern 200, as previously described in FIGS. 14 to 16. When the thickness of the channel pattern 200 becomes thin through this process, the floating body effect may be minimized and defects in the channel pattern may be easily controlled.

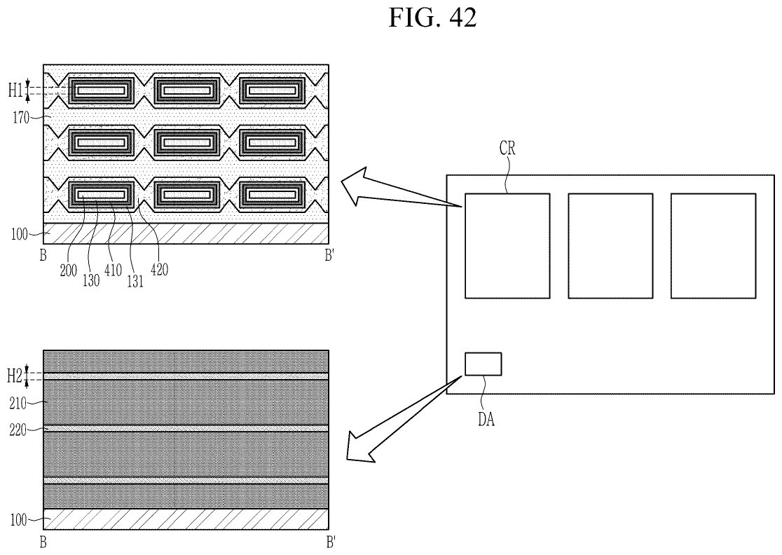

However, this is an example, and the thickness of the channel pattern 200 in the cell region CR may be the same as the thickness of the channel layer 220 in the dummy region DA. FIG. 42 shows a plan view of an integrated circuit memory device according to another embodiment. Referring to FIG. 42, the integrated circuit memory device may include a cell region CR and a dummy region DA. The stacking structure of the cell region CR is as described above. The dummy region DA may have a stacking structure as shown in FIGS. 9 and 10. That is, the dummy region DA may have a structure in which the channel layers 220 and the sacrificial layers 210 are alternately stacked. In the embodiment of FIG. 42, the thickness H1 of the channel pattern 200 included in the cell region CR may be the same as the thickness H2 of the channel layer 220 included in the dummy region DA. Unlike the embodiment of FIG. 41, the integrated circuit memory device according to the present embodiment may not include a process of reducing the thickness of the channel pattern 200 in the process of patterning the channel layer 220 to form the channel pattern 200, in which case the thickness of the channel pattern 200 included in the cell region CR may be the same as the thickness of the channel layer 220 included in the dummy region DA.

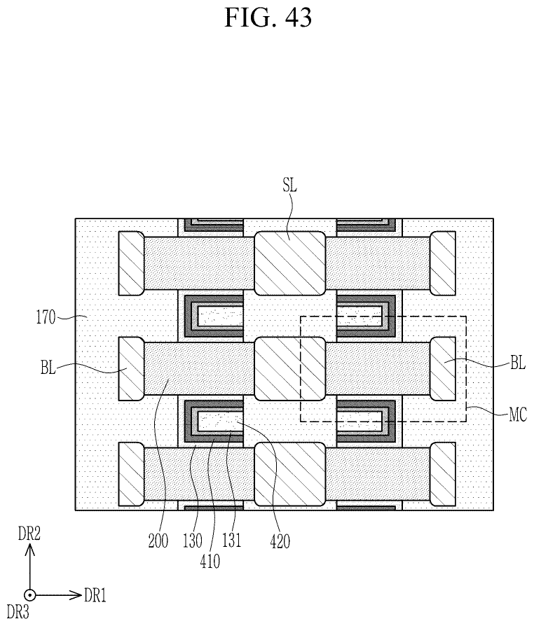

Additionally, in the previous embodiment, a configuration in which the dummy pattern 180 remains in the integrated circuit memory device has been described, but in an integrated circuit memory device according to another embodiment, the dummy pattern 180 may be removed and may not remain in the final integrated circuit memory device. FIG. 43 shows the same cross-section as FIG. 2 of an integrated circuit memory device according to another embodiment. Referring to FIG. 43, the integrated circuit memory device according to the present embodiment is the same as the embodiment of FIG. 2 except that it does not include the dummy pattern 180. Detailed descriptions of the same components are omitted.

Comparing FIG. 43 with FIG. 2, the embodiment of FIG. 43 does not include the dummy pattern 180. In the above-described manufacturing method, as shown in FIGS. 26 to 28, it may be manufactured by etching the whole dummy pattern 180 without leaving the dummy pattern 180 in the process of etching the dummy pattern 180 surrounding the channel pattern 200.

That is, when the dummy pattern 180 is etched to partially remain as shown in FIGS. 26 to 28, the integrated circuit memory device of FIG. 2 is manufactured, and when etching is performed without leaving any dummy pattern 180, the integrated circuit memory device shown in FIG. 43 may be manufactured. In addition, although the integrated circuit memory device according to the previous embodiment has been described as having a configuration including both the internal metal layer 410 and the external metal layer 420, an integrated circuit memory device according to another embodiment may not include the internal metal layer 410.

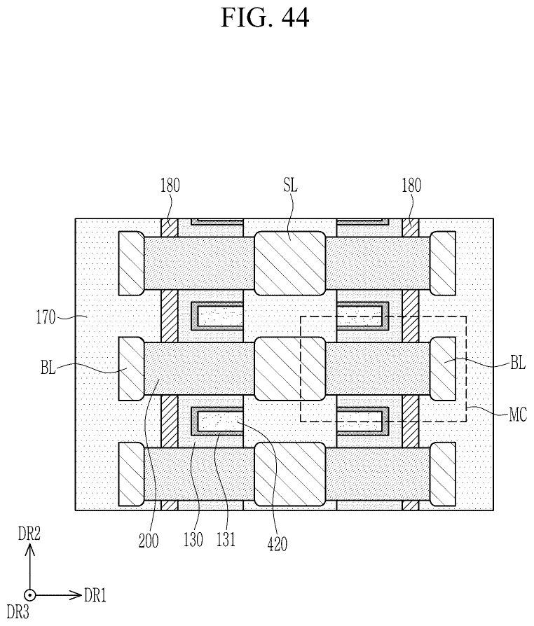

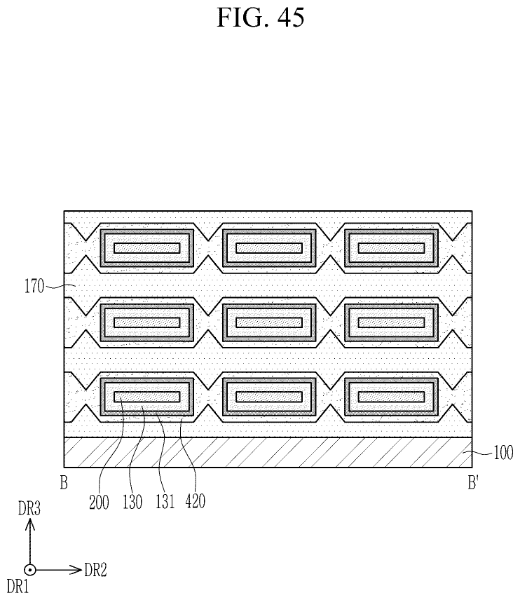

FIG. 44 shows the same cross-section as FIG. 2 of an integrated circuit memory device according to another embodiment. FIG. 45 shows the same cross- section as FIG. 3 of an integrated circuit memory device according to another embodiment. Referring to FIGS. 44 and 45, the integrated circuit memory device according to the present embodiment is the same as the embodiment of FIGS. 2 and 3 except that it does not include the internal metal layer 410. Detailed descriptions of the same components are omitted.

In the embodiment of FIGS. 44 and 45, the gate insulating layer 130 may include HfNₓ. At this time, x may be between 1.05 and 1.15. Additionally, the ferroelectric layer 131 may have a structure in which layers containing HfN_{1.3} and layers containing HfN_{1.1} are alternately stacked. However, this structure is only an example and the present disclosure is not limited thereto.

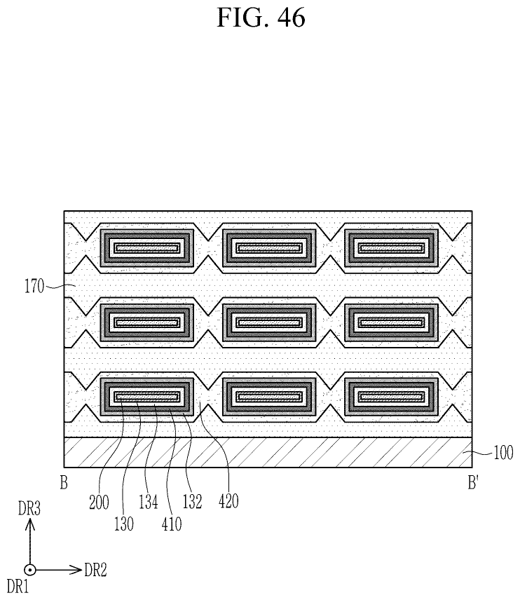

FIG. 46 shows the same cross-section as FIG. 3 of an integrated circuit memory device according to another embodiment. Referring to FIG. 46, the integrated circuit memory device according to the present embodiment may include the gate insulating layer 130 surrounding the channel pattern 200, a fixed charge layer 134 surrounding the gate insulating layer 130, the internal metal layer 410 surrounding the fixed charge layer 134, an antiferroelectric layer 132, and the external metal layer 420. Compared to the embodiment of FIG. 3, the embodiment of FIG. 46 is same as the embodiment of FIG. 3 except that the embodiment of FIG. 46 includes the antiferroelectric layer 132 instead of the ferroelectric layer 131, and the fixed charge layer 134 is disposed between the gate insulating layer 130 and the internal metal layer 410. Detailed descriptions of the same components are omitted.

The antiferroelectric layer 132 may include antiferromagnetic materials. For example, the antiferroelectric layer 132 may include at least one from the group consisting of hafnium oxide (HfO₂), zirconium oxide (ZrO₂), hafnium-zirconium oxide (HfₓZr₁₋ₓO₂, where 0<x<1), PbZrO₃, PbHfO₃, and a combination thereof. The fixed charge layer 134 may include an oxide-for example, any one of SiO₂, HfO₂, ZrO₂, TiO₂, VO, Nb₂O₅, Ta₂O₅, Al₂O₃, Y₂O₃, and Ln₂O₃.

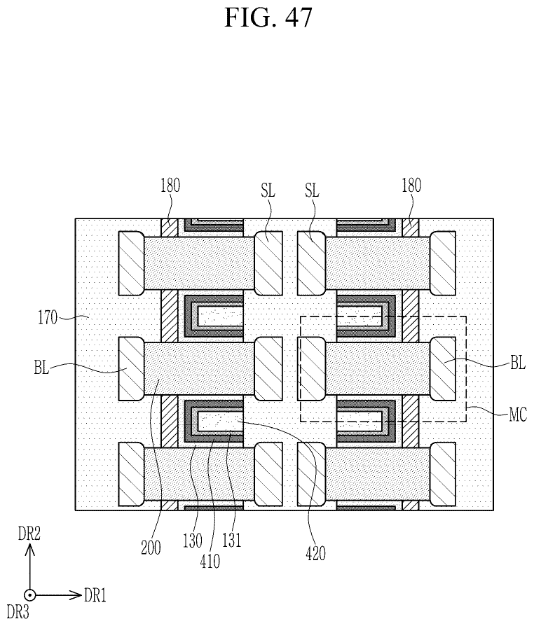

FIG. 47 shows the same cross-section as FIG. 2 for another embodiment. Referring to FIG. 47, the integrated circuit memory device according to the present embodiment is the same as the embodiment of FIG. 2 except that the source line SL is separated for each channel pattern 200. Detailed descriptions of the same components are omitted. That is, in the embodiment of FIG. 2, channel patterns 200 that are adjacent to each other in the first direction DR1 are connected to one source line SL, but in the embodiment of FIG. 47, the channel patterns 200 adjacent to each other in the first direction DR1 may be connected to each source line SL.

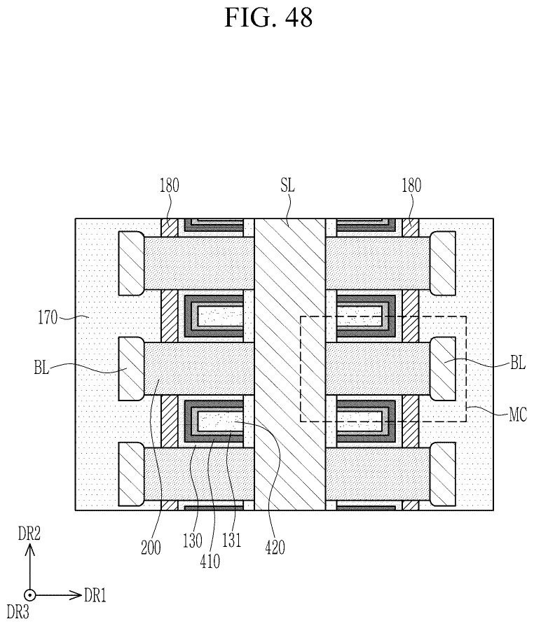

FIG. 48 shows the same cross-section as FIG. 2 for another embodiment. FIG. 48 is the same as the embodiment of FIG. 2 except that more channel patterns 200 than in FIG. 2 are connected to one source line SL. Detailed descriptions of the same components are omitted. Referring to FIG. 48, the plurality of channel patterns 200 adjacent in the first direction DR1 and the second direction DR2 may be connected to one source line SL.

As described above, the integrated circuit memory device according to the present embodiment includes the channel pattern 200 extending in the first direction DR1 between the bit line BL and the source line SL, which extend in the third direction DR3, and the channel pattern 200 is surrounded by the gate insulating layer 130, the internal metal layer 410, the ferroelectric layer 131, and the external metal layer 420. The external metal layer 420 surrounding each channel pattern 200 may be joined as one in the second direction DR2 to form the word line WL. This structure may minimize the size of the unit memory cell, improve the memory window, and improve the durability of the gate insulating layer. In other words, the operating characteristics of the integrated circuit memory device may be improved.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. An integrated circuit memory device, comprising:
a substrate including a cell region therein;
a plurality of bit lines extending in a direction perpendicular to the substrate;
a plurality of channel patterns having one end connected to each bit line and extending in a first direction intersecting an extension direction of the bit line; and
a gate insulating layer, an internal metal layer, a ferroelectric layer, and an external metal layer surrounding each of the channel patterns; and
wherein the external metal layers surrounding the corresponding channel patterns are connected to each other in a second direction intersecting the first direction.

2. The device of claim 1, wherein each of the channel patterns, and the corresponding gate insulating layer, internal metal layer, ferroelectric layer, and external metal layer surrounding each respective channel pattern, are configured as a respective memory cell; and wherein an insulating layer extends between a plurality of the memory cells.

3. The device of claim 2, further comprising a dummy pattern surrounding a corresponding channel pattern; and wherein the dummy pattern is in direct contact with a gate insulating layer.

4. The device of claim 3, wherein the dummy pattern includes a material different from the insulating layer.

5. The device of claim 2, wherein the insulating layer extends between the channel patterns in a third direction perpendicular to the substrate, and extends along the second direction.

6. The device of claim 5, wherein the thickness of the insulating layer in the third direction extending along the second direction is different in a region where the channel pattern is disposed and a region where the channel pattern is not disposed.

7. The device of claim 2, wherein the gate insulating layer, the internal metal layer, the ferroelectric layer, and the external metal layer are in direct contact with the insulating layer.

8. The device of claim 1, wherein each of internal insulating layers surrounding the plurality of channel patterns is connected to each other in the second direction.

9. The device of claim 1, wherein the ferroelectric layers surrounding the corresponding plurality of channel patterns are connected to each other in the second direction.

10. The device of claim 1, further comprising a source line extending in the third direction perpendicular to the substrate; and wherein one end of the channel pattern is connected to the source line.

11. The device of claim 10, wherein two channel patterns adjacent in the first direction are connected to the same source line.

12. The device of claim 11, wherein two or more channel patterns adjacent in the second direction are connected to the same source line.

13. The device of claim 1, further comprising a circuit region overlapping the cell region in the third direction perpendicular to the substrate.

14. The device of claim 1, wherein the substrate further comprises a circuit region; and wherein the cell region and the circuit region are disposed side by side.

15. The device of claim 1, wherein the substrate further comprises a dummy region; wherein the dummy region comprises alternately stacked channel layers and sacrificial layers; wherein the channel layers comprise the same material as the channel patterns; and wherein the thickness of the channel layer is greater than the thickness of the channel pattern in the cell region.

16. An integrated circuit memory device, comprising:
a substrate;
a plurality of bit lines extending in a direction perpendicular to the substrate;
a plurality of channel patterns having one end connected to each bit line and extending in a first direction intersecting an extension direction of the bit line; and
a gate insulating layer, a ferroelectric layer, and an external metal layer surrounding each channel pattern; and
wherein the external metal layers surrounding the channel patterns are connected to each other in a second direction intersecting the first direction.

17. The device of claim 16, wherein the gate insulating layer comprises HfNₓ, where x is between 1.05 and 1.15; and wherein the ferroelectric layer includes a stack of alternating HfN_{1.3} and HfN_{1.1} layers.

18. An integrated circuit memory device, comprising:
a substrate;
a plurality of bit lines extending in a direction perpendicular to the substrate;
a plurality of channel patterns having one end connected to each bit line and extending in a first direction intersecting an extension direction of the bit line;
a gate insulating layer, an internal metal layer, a fixed charge later, an internal metal layer, an antiferroelectric layer, and an external metal layer surrounding each of the channel patterns; and
an insulating layer extending between the channel patterns; and
wherein the external metal layers surrounding the channel patterns are connected to each other in a second direction intersecting the first direction.

19. The device of claim 18, wherein the gate insulating layer, the fixed charge layer, the internal metal layer, the antiferroelectric layer, and the external metal layer are in direct contact with the insulating layer.

20. The device of claim 18, further comprising:
a dummy pattern that surrounds the channel pattern, and is in direct contact with the gate insulating layer.
